(19) United States
(12) Patent Application Publication
(10) Pub. No.: US 2025/0218992 A1
(43) Pub. Date: Jul. 3, 2025

(54) CORE-SHELL BALL GRID ARRAY MATERIALS FOR LARGE FORM FACTOR INTEGRATED CIRCUIT PACKAGES

(71) Applicant: Intel Corporation, Santa Clara, CA (US)

(72) Inventors: Rui Zhang, Chandler, AZ (US); Jiaqi Wu, Chandler, AZ (US); Brian Franco, Portland, OR (US); Xiao Lu, Chandler, AZ (US); Mukul Renavikar, North Plains, OR (US)

(73) Assignee: Intel Corporation, Santa Clara, CA (US)

(21) Appl. No.: 18/399,395

(22) Filed: Dec. 28, 2023

(51) Int. Cl. H01L 23/00

(52) U.S. Cl. CPC H01L 24/13; H01L 24/16; H01L 2224/13082; H01L 2224/13111; H01L 2224/13113; H01L 2224/1312; H01L 2224/13139; H01L 2224/13147; H01L 2224/13655; H01L 2224/16227

(57) ABSTRACT

Solder materials, solder balls, and solder features, and microelectronic devices and systems deploying the solders are discussed. A solder ball includes an inner core that is an alloy of tin, silver, and copper, which has a relatively high melting point. Surrounding the inner core is a shell or cladding of a tin-bismuth alloy having a lower melting point. An optional nickel coating is on the inner core and between the inner core and the shell or cladding. During surface mount, the lower melting point the tin-bismuth alloy is used as the reflow temperature.

### BACKGROUND

The electronics industry is continually striving to produce ever faster, more efficient, and more powerful computing products. With the advancement of artificial intelligence (AI), internet of things (IoT), cloud computing, telecommunication, and other technologies, the demand for high-performance computing (HPC) products is on the rise. Heterogeneous integration is one technology that is being deployed to address these increasing product demands. In heterogeneous integration, the die complex area per package is, in turn, increasing from about 1,600 mm² to 4,800-6,400 mm² or more. As a result, the package form factor increases, which results in higher warpage during the surface mount technology (SMT) process that attaches the package to a microelectronics board such as a motherboard. For 1 mm pitch ball gride array (BGA) packages, current solders such as tin-silver-copper (SAC) solders have high failure rates at about 2,000 mm² die complex areas. For increasing die complex and corresponding package area sizes, reducing the reflow peak temperature with low temperature solder (LTS) is a promising approach. However, current LTS material systems have drawbacks including reduced current carrying capability, reliability problems, and others. It is with respect to these and other considerations that the present improvements have been needed. Such improvements may become critical as the desire to improve computing device performance becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a solder ball including an inner core and a shell surrounding the inner core;

FIG. 1B illustrates a cross-sectional side view of an integrated circuit assembly including a solder ball interconnect structure having an inner core and a shell surrounding the inner core such that the solder ball interconnect structure electrically couples metallization structures;

FIG. 2A illustrates a cross-sectional side view of a solder ball including an inner core, a shell surrounding the inner core, and a barrier layer on the inner core and between the inner core and the shell;

FIG. 2B illustrates a cross-sectional side view of an integrated circuit assembly including a solder ball interconnect structure having an inner core, a shell surrounding the inner core, and a barrier layer on the inner core and between the inner core and the shell such that solder ball interconnect structure electrically couples metallization structures;

FIG. 3 is a flow diagram illustrating an example process for fabricating a solder ball including an inner core and a shell surrounding the inner core;

FIGS. 4, 5, and 6 are illustrations of materials and workpieces as the operations of the process of FIG. 3 are performed to fabricate a solder ball including an inner core and a shell surrounding the inner core;

FIG. 7 is a flow diagram illustrating an example process for assembling a device or system including a solder ball interconnect structure having an inner core and a shell of different metal alloys;

FIGS. 8, 9, 10, and 11 cross-sectional side views of integrated circuit device structures as the operations of process FIG. 7 are performed to assemble a device or system including a solder ball interconnect structure having an inner core and a shell of different metal alloys;

FIG. 12 is a cross-sectional top-down view of the integrated circuit device structure of FIG. 11 showing an exemplary integrated circuit die layout;

FIG. 13 is a cross-sectional top-down view of the integrated circuit device structure of FIG. 11 showing an exemplary solder interconnect layout;

FIG. 14 is a cross-sectional side view of the integrated circuit device structure of FIG. 11 after incorporation into a system;

FIG. 15 illustrates exemplary systems employing an assembly including a solder ball interconnect structure having an inner core and a shell of different metal alloys; and

FIG. 16 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on weight percentage.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure.

As used herein, the terms “monolithic”, “monolithically integrated”, and similar terms indicate the components of the monolithic overall structure form an indivisible whole not reasonably capable of being separated. The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials. Here, the term “coreless” generally refers to a substrate of an integrated circuit package having no core. The lack of a core allows for higher-density package architectures. as the through-vias have relatively large dimensions and pitch compared to high-density interconnects.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “bond pad” generally refers to metallization structures that terminate integrated traces and vias in integrated circuit packages and dies. The term “solder pad” may be occasionally substituted for “bond pad” and carries the same meaning. Here, the term “solder bump” generally refers to a solder layer formed on a bond pad. The solder layer typically has a round shape, hence the term “solder bump”. Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Solder balls, solder materials, apparatuses, microelectronic assemblies, systems, and techniques are described herein related to solder balls having a core of a first metal alloy such as tin-silver-copper (SAC) and an outer shell of a low temperature solder (LTS) such as tin-bismuth.

As discussed, as die complex and package areas increase, there is a corresponding higher warpage during the surface mount technology (SMT) process that attaches the package to a microelectronics board such as a motherboard. This causes attachment failures, broken connections, and other problems. Currently, there are a number of approaches to mitigate or resolve this issue including increasing the substrate core thickness, changing the substrate core material to a stiffer material, or increasing the thickness of the stiffener and/or lid used in the package. However, such changes are expensive and disruptive while the high temperature warpage reduction may not be significant enough for future size increases. Furthermore, increasing the overall system Z height is undesirable. Alternatively, multiple tin-silver-copper (SAC) solders ball sizes may be used on the same package to counter the high temperature warpage shape (e.g., using larger balls on locations where open risk is high and smaller balls on locations where bridging risk is high). However, such approaches are difficult to deploy in multiple different applications, and the need for very accurate ball sizes can lead to failures. Other difficulties arise such as manufacturing complexity and the inability for the different ball sizes to accommodate the warpage in some applications.

Reducing the reflow peak temperature with low temperature solder (LTS) materials is a promising approach to eliminate or mitigate warpage problems in SMT processing. For example, current SAC solders reflow at a temperature of about 240° C. By reducing the reflow temperature to about 190° C. or less, the warpage is reduced to a point where large area die complexes/packages can be readily attached without warpage concerns. For example, die complex areas of greater than 1,600 mm², such as those of 4,800 to 6,400 mm² or more, can be reliably attached without warpage problems at reflow temperatures of about 190° C. However, current low temperature solders such as tin-bismuth solders have limitations. While tin-bismuth alloys are compatible with low temperature SMT processing, in use the bismuth element migrates along the electron flow direction, which results in bismuth segregation on the anode side. As a result, the resistance of the solder interconnect increases, and the mechanical integrity of the joint can be compromised due to the high resistivity and brittleness of bismuth. For example, tin-bismuth (i.e., Sn—Bi) based solders have reduced current carrying capability and mechanical problems compared to SAC. This limits its deployment in, for example, high-performance computing (HPC) products which require the solder interconnects (e.g., BGA interconnects) to carry high current.

The techniques and structures discussed herein provide a solder ball having an inner core that is a first metal alloy such as SAC and a surrounding shell that is a second metal alloy such as a tin-bismuth alloy, optionally including dopants. For example, a ball grid attach (BGA) ball or sphere in accordance with the present disclosure includes a core-shell structure to significantly improve the current carrying capability of the resultant interconnect and to have the same SMT process margin with respect to completely tin-bismuth (SnBi) LTS BGA materials. The SAC/LTS core-shell BGA materials may be used in any context and can enable ultra-large form factor high power BGA packages.

The core-shell solder balls discussed herein include a core material (e.g., metal alloy) having advantageous electrical properties such as the ability to handle high current loads/power requirements inclusive of meeting demand for 2 A power supply, for example, as well as advantageous mechanical properties such as the ability to maintain mechanical integrity under such high current loads/power requirements. The core-shell solder balls further include a shell or cladding material surrounding the core material. The shell or cladding material (e.g., metal alloy) is different and has a lower melting temperature. Advantageously, the shell or cladding material allows for a lower reflow temperature (e.g., about 190° C.) that drastically reduces substrate warpage during SMT processing. Thereby, the core-shell solder balls may be attached at a relatively low temperature for reduced warpage and therefore SMT processing with reduced substrate damage, increased reliability, and other advantages. In usage, the core-shell solder ball maintains an acceptably low resistance over the course of electrical stress of the core-shell solder ball. Furthermore, during such usage, the core-shell solder ball also maintains its mechanical integrity over the course of the electrical stress. Thereby, the core-shell solder ball of the present disclosure resolves difficulties associated with reliable SMT in large and ultra-large form factor packages as well as difficulties associated with current carrying ability and long term reliability of the resultant solder material structure. In some embodiments, the core-shell solder ball has SAC as the core material and tin-bismuth (SnBi) as the shell material. Furthermore, a reliable and low-cost manufacturing process is discussed fabricate the core-shell solder balls.

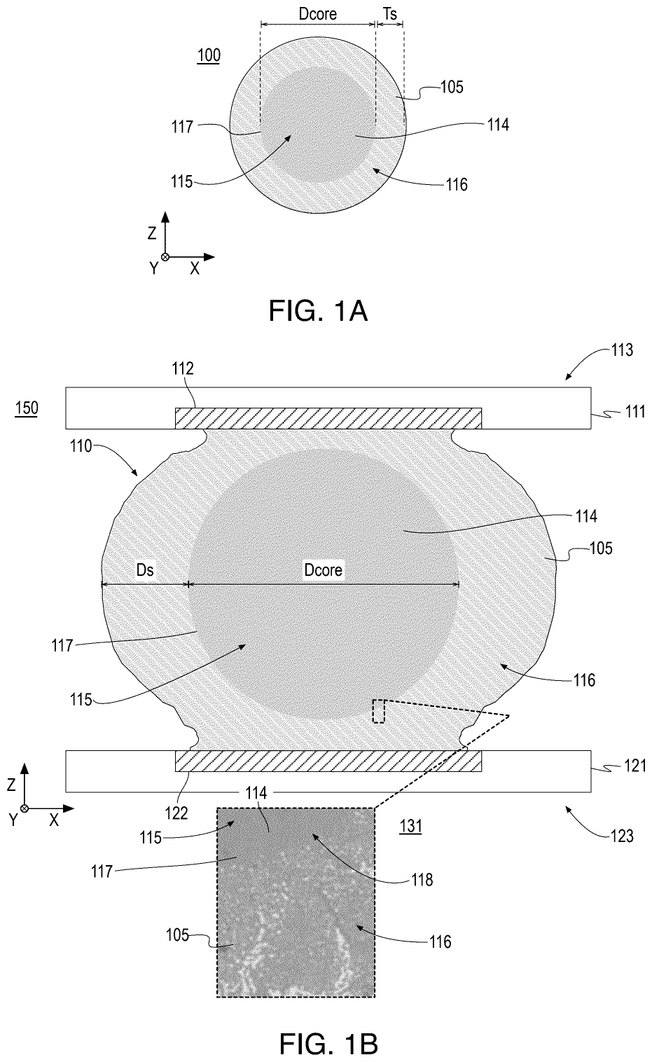

FIG. 1A illustrates a cross-sectional side view of a solder ball 100 including an inner core 114 and a shell 105 surrounding inner core 114, arranged in accordance with some embodiments. FIG. 1B illustrates a cross-sectional side view of an integrated circuit assembly 150 including a solder ball interconnect structure 110 having inner core 114 and a shell 105 surrounding inner core 114 such that solder ball interconnect structure 110 electrically couples metallization structures 112, 122, arranged in accordance with some embodiments. As shown in FIG. 1A, solder ball 100 includes inner core 114 and shell 105 surrounding inner core 114. As used herein, the term solder ball is used to indicate a ball prior to interconnection or an interconnect after interconnection inclusive of interconnects characterized as solder bumps, microbumps, coined solder balls, and the like as is consistent with the use of the term in the art.

As shown in FIG. 1B, solder ball interconnect structure 110 extends between and contacts each of metallization structure 112 and metallization structure 122. Metallization structure 112 may be embedded within a dielectric material 111, and metallization structure 112 and dielectric material 111 may be part of an integrated circuit (IC) device 113, such as an IC package. Metallization structure 122 may be embedded within a dielectric material 121, and metallization structure 122 and dielectric material 121 may be part of a host component 123, such as microelectronics board inclusive of a motherboard. Solder ball interconnect structure 110 may be part of a ball grid array (BGA) interconnect structure or any other suitable form factor interconnect architecture. Solder ball 100 and solder ball interconnect structure 110 may share any suitable characteristics discussed herein below.

With reference to FIGS. 1A and 1B, solder ball 100 and solder ball interconnect structure 110 include inner core 114, which is a metal alloy having a greater melting temperature than the metal alloy of shell 105. As used herein, the term inner core indicates a material at and surrounding a center or centroid of solder ball 100 and solder ball interconnect structure 110. The center or centroid of inner core 114 need not be at the same position of the center or centroid of solder ball 100 and solder ball interconnect structure 110. Furthermore, inner core 114 is surrounded by shell 105. Inner core 114 may be completely surrounded by shell 105 or substantially surrounded by shell 105 such that some of inner core 114 is exposed. In some embodiments, inner core 114 is completely surrounded by shell 105 such that no surface of inner core 114 is exposed.

Shell 105, which may be characterized as a cladding, coating, or the like surrounds inner core 114 such that a thickness of shell 105 covers all more nearly all of inner core 114. In some embodiments, shell 105 is directly on and in contact with inner core 114, as shown in FIGS. 1A and 1B. In other embodiments, a coating is between shell 105 and inner core 114 as discussed further herein below.

In some embodiments, inner core 114 is an alloy of tin, silver, and copper (SAC). In some embodiments, inner core 114 is about 96.5 wt. % tin, about 3 wt. % silver, and about 0.5 wt. % copper. However, any proportions of tin, silver, and copper may be used. In some embodiments, portions of inner core 114 may be penetrated by a metal or metals of shell 105 such that, for example, at least an inner portion 115 of inner core 114 is about 96.5 wt. % tin, about 3 wt. % silver, and about 0.5 wt. % copper while other portions at or near an interface 117 between inner core 114 and shell 105 includes one or more metals of shell 105. As used herein, the term portion indicates any suitable sample size volume to determine the contents thereof.

In some embodiments, shell 105 is an alloy of tin and bismuth (i.e., SnBi). Shell 105 may also further optionally include a dopant material. For example, the dopant material or materials may further slow the migration of bismuth during operation. As discussed, solders including tin and bismuth have a relatively low reflow temperature so IC device 113 and/or host component 123 do not have warpage problems when IC device 113 is attached to host component 123. For example, at the reflow temperature of solder ball interconnect structure 110, which is about 190° C. or less, dielectric material 111 and/or dielectric material 121 may not warp to an extent that they do not be reliably bonded together in a SMT process that bonds IC device 113 and host component 123. In some embodiments, shell 105 is a eutectic compound of tin and bismuth. As used herein, the term eutectic compound indicates a compound or mixture of constituent elements having a lower melting point than that of the constituent elements. In eutectic compounds or mixtures, the solidus and liquidus temperatures are the same. In some embodiments, shell 105 is an off-eutectic compound of tin and bismuth. As used herein, the term off-eutectic compound indicates a compound or mixture of constituent elements where the solidus and liquidus temperatures are different.

In some embodiments, at least a bulk portion 116 of shell 105 includes an alloy of tin and bismuth, and optional dopant material. The alloy of tin and bismuth may include any suitable proportions of tin and bismuth. In some embodiments, shell 105 is substantially pure tin and bismuth (i.e., tin-bismuth). In some embodiments, shell 105 is pure tin and bismuth (i.e., tin-bismuth). In some embodiments, shell 105 is not less than 30 wt. % bismuth and a balance of tin. In some embodiments, shell 105 is not less than 40 wt. % bismuth and a balance of tin. In some embodiments, shell 105 is not less than 50 wt. % bismuth and a balance of tin. In some embodiments, shell 105 is not more than 57% wt. % bismuth and a balance of tin. In some embodiments, shell 105 is not less than 30 wt. % and not more than 57% wt. % bismuth, and a balance of tin. In some embodiments, shell 105 is substantially pure tin-bismuth with not less than 30 wt. % and not more than 57% wt. % bismuth, and a balance of tin.

As discussed, shell 105 may further include one or more dopants. In some embodiments, shell 105 includes not less than 0.1 wt. % silver. In some embodiments, shell 105 includes not less than 0.5 wt. % silver. In some embodiments, shell 105 includes not more than 1 wt. % silver. In some embodiments, shell 105 includes not less than 0.1 wt. % and not more than 1 wt. % silver. In some embodiments, shell 105 is not less than 30 wt. % bismuth, between 0.1 and 1 wt. % silver, and a balance of tin. In some embodiments, shell 105 is not less than 40 wt. % bismuth, between 0.1 and 1 wt. % silver, and a balance of tin. In some embodiments, shell 105 is not less than 50 wt. % bismuth, between 0.1 and 1 wt. % silver, and a balance of tin. In some embodiments, shell 105 is not more than 57% wt. % bismuth, between 0.1 and 1 wt. % silver, and a balance of tin. In some embodiments, shell 105 is not less than 30 wt. % and not more than 57% wt. % bismuth, between 0.1 and 1 wt. % silver, and a balance of tin.

In some embodiments, shell 105 includes not less than 0.1 wt. % antimony. In some embodiments, shell 105 includes not less than 0.5 wt. % antimony. In some embodiments, shell 105 includes not more than 1 wt. % antimony. In some embodiments, shell 105 includes not less than 0.1 wt. % and not more than 1 wt. % antimony. In some embodiments, shell 105 is not less than 30 wt. % bismuth, between 0.1 and 1 wt. % antimony, and a balance of tin. In some embodiments, shell 105 is not less than 40 wt. % bismuth, between 0.1 and 1 wt. % antimony, and a balance of tin. In some embodiments, shell 105 is not less than 50 wt. % bismuth, between 0.1 and 1 wt. % antimony, and a balance of tin. In some embodiments, shell 105 is not more than 57% wt. % bismuth, between 0.1 and 1 wt. % antimony, and a balance of tin. In some embodiments, shell 105 is not less than 30 wt. % and not more than 57% wt. % bismuth, between 0.1 and 1 wt. % antimony, and a balance of tin.

As shown with respect to enlarged view 131, in some embodiments, shell 105 is directly on and in contact with inner core 114 at interface 117. In some embodiments, inner core 114 may include bismuth from shell 105. For example, there may be some penetration of bismuth into inner core 114 during fabrication of solder ball 100 and/or during formation of solder ball interconnect structure 110 (e.g., during reflow of shell 105). In some embodiments, shell 105 is directly on inner core 114, and inner core 114 includes bismuth at, for example, portion 118. The proportion of bismuth in portion 118 of inner core 114 may be any suitable amount such as less than 1 wt. % bismuth. In some embodiments, the proportion of bismuth in portion 118 of inner core 114 is not more than 1 wt. % bismuth. In some embodiments, the proportion of bismuth in portion 118 of inner core 114 is not more than 0.5 wt. % bismuth. In some embodiments, the proportion of bismuth in portion 118 of inner core 114 is not less than 0.01 wt. % bismuth. In some embodiments, the proportion of bismuth in portion 118 of inner core 114 is not less than 0.1 wt. % bismuth. In some embodiments, the proportion of bismuth in portion 118 of inner core 114 is not less than 0.2 wt. % bismuth.

Inner core 114 and shell 105 may have any suitable lateral widths and thicknesses, respectively. In some embodiments, inner core 114 has a lateral width (i.e., a maximum cross-sectional dimension in the x-y plane) of between about 200 to 700 microns. For example, the lateral width may be a diameter Dcore. However, the lateral width may be the cross-sectional dimension of any suitable shape in the x-y plane. In some embodiments, core 114 has a cross-sectional dimension of not less than 200 microns and not more than 700 microns. In some embodiments, core 114 has a cross-sectional dimension of not less than 450 microns and not more than 610 microns. Other cross-sectional dimensions may be used.

In some embodiments, shell 105 has a thickness Ts (i.e., a distance measured orthogonal from surface position of inner core 114 of between about 0.8 to 150 microns. In some embodiments, the thickness Ts of shell 105 is not less 0.8 microns. In some embodiments, the thickness Ts of shell 105 is not less 10 microns. In some embodiments, the thickness Ts of shell 105 is not less 20 microns. In some embodiments, the thickness Ts of shell 105 is not less 50 microns. In some embodiments, the thickness Ts of shell 105 is not less 100 microns. In some embodiments, the thickness Ts of shell 105 is not more than 150 microns. In some embodiments, the thickness Ts of shell 105 is not less 0.8 microns and not more than 150 microns.

Thus, a wide range of shell 105 thickness Ts to inner core 114 diameter Dcore is available due to the hybrid nature of solder ball 100 and solder ball interconnect structure 110. In some embodiments, thickness Ts is not less than 1% of the cross-sectional dimension of inner core 114. In some embodiments, thickness Ts is not less than 10% of the cross-sectional dimension of inner core 114. In some embodiments, thickness Ts is not less than 25% of the cross-sectional dimension of inner core 114. In some embodiments, thickness Ts is not less than 50% of the cross-sectional dimension of inner core 114. In some embodiments, thickness Ts is not less than 75% of the cross-sectional dimension of inner core 114. In some embodiments, a combined cross-sectional dimension of shell 105 thickness Ts and inner core 114 diameter Dcore (i.e., Ts+Dcore) is designed to be a particular desired interconnect dimension. For example, the combined lateral dimension or lateral width of between about 200 to 700 microns. In some embodiments, solder ball interconnect structure 110 has a vertical height (i.e., a dimension in the z-direction) of between about 150 to 300 microns. The vertical height of solder ball interconnect structure 110 may also define the vertical offset between IC device 113 and host component 123. Other sizes and aspect ratios may be used for solder ball interconnect structure 110.

As discussed, and with reference to FIG. 1B, integrated circuit assembly 150 includes metallization structure 122 of host component 123, metallization structure 112 of IC device 113, and solder ball interconnect structure 110 coupling metallization structure 122 and metallization structure 112. Solder ball interconnect structure 110 includes inner core 114, which may be characterized as an inner metal core, and includes tin, silver, and copper, and shell 105, which may be characterized as a metal shell, a cladding, or a metal cladding, surrounding inner core 114, such that shell 105 includes tin and bismuth. Notably, inner core 114 has a substantially greater melting point relative to shell 105. Advantageously, shell 105 melts at a lower temperature such that a bond may be formed between host component 123 and IC device 113 at a relatively low temperature such as a reflow temperature of about 190° C. Thereby, warpage of host component 123 and/or IC device 113 is mitigated (i.e., due to the lower reflow temperature) and reliable interconnect bonding is enabled. In some embodiments, the difference between the melting points of the metal alloy of inner core 114 and the metal alloy of shell 105 is not less than 40° C. In some embodiments, the difference between the melting points of the metal alloy of inner core 114 and the metal alloy of shell 105 is not less than 60° C. In some embodiments, the difference between the melting points of the metal alloy of inner core 114 and the metal alloy of shell 105 is not less than 80° C. For example, inner core 114 may have a melting point of between about 210° C. and 240° C., and shell 105 may have a melting point of between about 138° C. and 170° C.

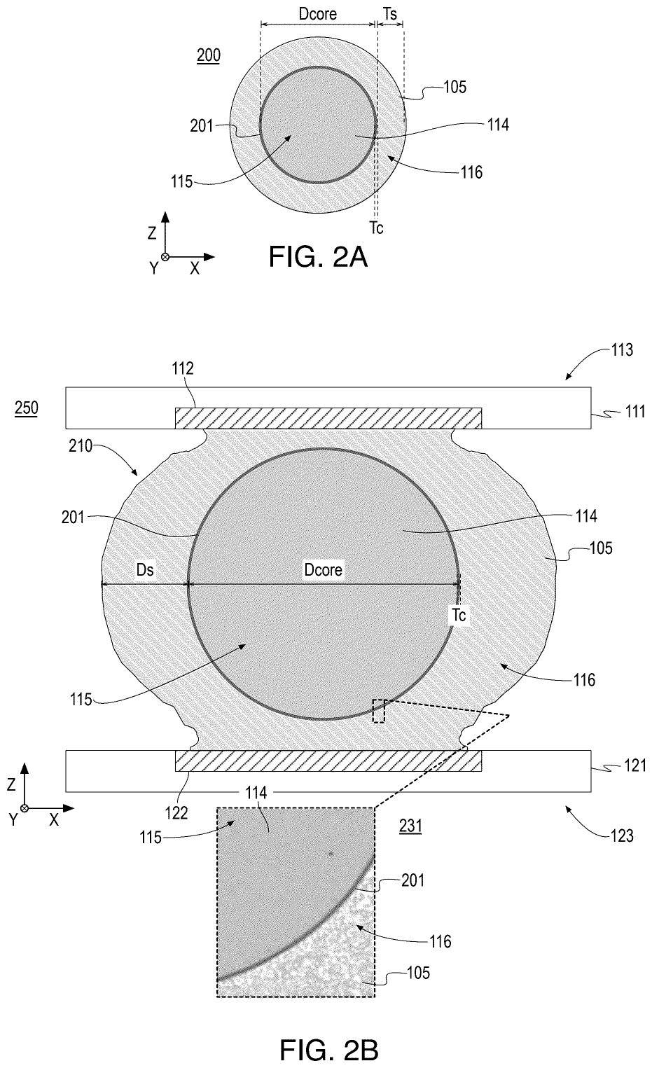

FIG. 2A illustrates a cross-sectional side view of a solder ball 200 including inner core 114, shell 105 surrounding inner core 114, and a barrier layer 201 on inner core 114 and between inner core 114 and shell 105, arranged in accordance with some embodiments. FIG. 2B illustrates a cross-sectional side view of an integrated circuit assembly 250 including a solder ball interconnect structure 210 having inner core 114, shell 105 surrounding inner core 114, and barrier layer 201 on inner core 114 and between inner core 114 and shell 105 such that solder ball interconnect structure 110 electrically couples metallization structures 112, 122, arranged in accordance with some embodiments.

As shown in FIG. 2A, solder ball 200 includes inner core 114 and shell 105 surrounding inner core 114. Inner core 114 and shell 105 may have any characteristics discussed elsewhere herein. As shown in FIG. 2B, solder ball interconnect structure 210 extends between and contacts each of metallization structure 112 and metallization structure 122. Metallization structures 112, 122, dielectric materials 111, 121, IC device 113, and host component 123 may also have any characteristics discussed elsewhere herein.

With reference to FIGS. 2A and 2B, solder ball 200 and solder ball interconnect structure 210 include barrier layer 201, which may be a thickness Tc of a metal including nickel. In some embodiments, barrier layer 201 is substantially pure nickel. In some embodiments, barrier layer 201 is pure nickel. In some embodiments, an intermetallic compound may be formed at barrier layer 201 such that the intermetallic compound is formed of nickel and one or both of tin and bismuth. As used herein, the term intermetallic compound indicates a metal alloy having an ordered solid-state structure. In some embodiments, an intermetallic compound has a particular stoichiometry of the alloyed materials. In some embodiments, the solid-state structure is a crystalline structure such that at least a portion of the intermetallic compound is crystalline. In some embodiments, the intermetallic compound is polycrystalline.

As shown with respect to enlarged view 231, in some embodiments, shell 105 is directly on and in contact with barrier layer 201 and barrier layer 201 is directly on and in contact with inner core 114. In some embodiments, barrier layer 201 substantially stops bismuth from shell 105 from penetrating inner core 114. For example, an entirety of inner core 114 may be absent bismuth due to application of inner core 114.

Inner core 114 and shell 105 may have any suitable lateral widths and thicknesses, respectively, as discussed above with respect to FIGS. 1A and 1B. Barrier layer 201 may also have any suitable lateral widths and thickness Tc (i.e., a distance measured orthogonal from a surface position of inner core 114). In some embodiments, the thickness Tc of barrier layer 201 is in the range of 1 to 5 microns. In some embodiments, the thickness Tc of barrier layer 201 is not less 1 micron. In some embodiments, the thickness Tc of barrier layer 201 is not less 2 microns. In some embodiments, the thickness Tc of barrier layer 201 is not less 4 microns. In some embodiments, the thickness Tc of barrier layer 201 is not more than 5 microns. In some embodiments, the thickness Ts of shell 105 is not less 1 micron and not more than 5 microns. Other thicknesses may be used.

With reference to FIG. 2B, integrated circuit assembly 250 includes metallization structure 122 of host component 123, metallization structure 112 of IC device 113, and solder ball interconnect structure 210 coupling metallization structure 122 and metallization structure 112. Solder ball interconnect structure 210 includes inner core 114, shell 105, and barrier layer 201, which may be characterized as a coating, a layer, a liner, or the like on inner core 114 and between inner core 114 and shell 105 such that shell 105 is on barrier layer. As discussed, barrier layer 201 includes nickel and may be substantially pure or pure nickel.

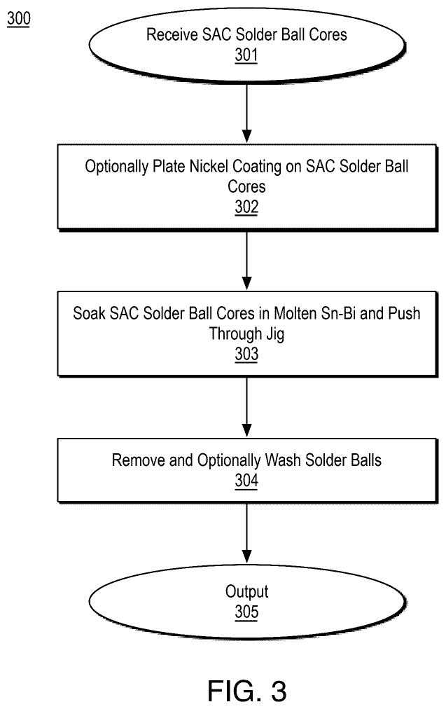

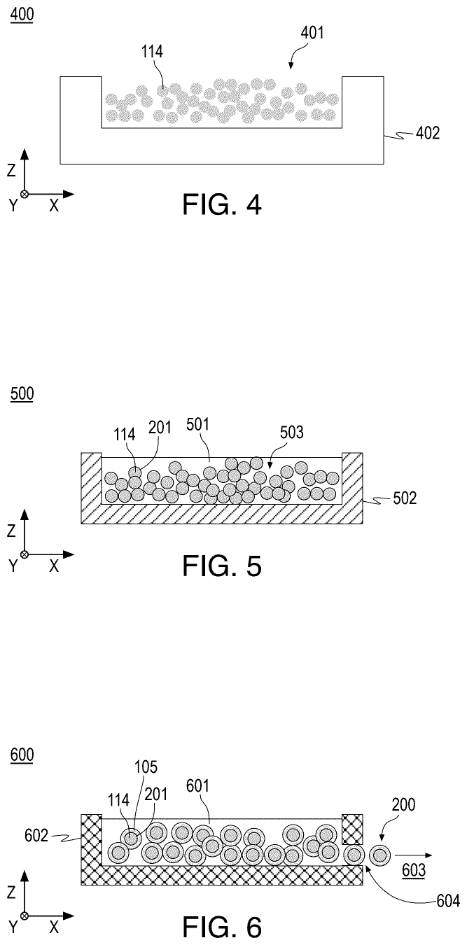

FIG. 3 is a flow diagram illustrating an example process 300 for fabricating a solder ball including inner core 114 and shell 105 surrounding inner core 114, arranged in accordance with some embodiments. Notably, process 300 may be used to fabricate solder balls with or without barrier layer 201. FIGS. 4, 5, and 6 are illustrations of materials and workpieces as the operations of process 300 are performed to fabricate a solder ball including inner core 114 and shell 105 surrounding inner core 114, arranged in accordance with some embodiments, arranged in accordance with some embodiments.

As shown, process 300 begins at operation 301, where the materials are received for processing. In some embodiments, solder balls having the desired material composition and size of inner core 114 are received for processing. Such received solder balls may have any characteristics discussed with respect to inner core 114 herein. In some embodiments, the received solder balls are SAC solder balls of about 96.5 wt. % tin, about 3 wt. % silver, and about 0.5 wt. % copper. However, solder balls having any compositions and sizes discussed herein may be used.

Processing continues at operation 302, where the solder balls received at operation 301 are optionally plated with a nickel coating or barrier layer. The nickel barrier layer may be formed on the SAC solder balls using any suitable technique or techniques. In some embodiments, the SAC solder balls are immersed in a nickel plating bath operated under appropriate conditions as known in the art to plate or coat the SAC solder balls with 1 to 5 microns of substantially pure or pure nickel.

FIG. 4 illustrates materials and workpieces 400 including receiving any number of solder balls 401 in a container 402 such that solder balls 401 having any characteristics discussed herein with respect to inner core 114. For example, solder balls 401 may include tin, silver, and copper. In some embodiments, solder balls 401 are 96.5 wt. % tin, about 3 wt. % silver, and about 0.5 wt. % copper. Furthermore, solder balls 401 may have any diameter or cross-sectional width discussed herein with respect to Dcore. For example, solder balls 401 may have a diameter or cross-sectional width in the range of 200 microns to 700 microns.

FIG. 5 illustrates materials and workpieces 500 during plating of solder balls 401 with barrier layer 201 to form plated solder balls 503. Barrier layer 201 may be formed on solder balls 401 using any suitable technique or techniques such as a plating operation by nickel plating barrier layer 201 on solder balls 401 in plating bath 501 using an electroplating apparatus 502 such as bead bath electroplater. In some embodiments, plating bath 501 is an electrolyte solution that is used as the cathode with the nickel anode being dissolved into the electrolyte solution to form nickel ions, which are deposited on solder balls 401 as barrier layer 201. Barrier layer 201 may have any characteristics discussed herein. For example, barrier layer may be substantially pure or pure nickel deposited to a thickness in the range of 1 to 5 microns.

Returning to FIG. 3, processing continues at operation 303, where the solder balls received at operation 301 or plated at operation 302 are coated with molten tin-bismuth (optionally including one or more dopants), pushed through a jig or form and cooled to form solder balls 100, 200. The tin-bismuth LTS solder shell may be formed using any suitable process conditions to form shell 105 having any characteristics discussed herein.

FIG. 6 illustrates materials and workpieces 600 during the coating of plated solder balls 503 with a tin-bismuth shell (optionally including one or more dopants) and subsequent passage through a form or jig 604 of process chamber 602 to output 603 solder balls 200. Although illustrated with respect to coating plated solder balls 503 to form solder balls 200, the same processing may be used to coat solder balls 401 to form solder balls 200. As discussed, in some embodiments, plated solder balls 503 are soaked in a molten tin-bismuth bath 601 to coat plated solder balls 503. The coated plated solder balls 503 are then passed through jig 604 to form them into the desired size and shape. Such coating and ball formation may be performed using any suitable technique or techniques.

Returning to FIG. 3, processing continues at operation 304, where the solder balls formed at operation 303 are removed and optionally washed, and at operation 305 where the solder balls are output for further processing, such as surface mount attachment of an IC device to a microelectronics board, for example, as discussed herein below.

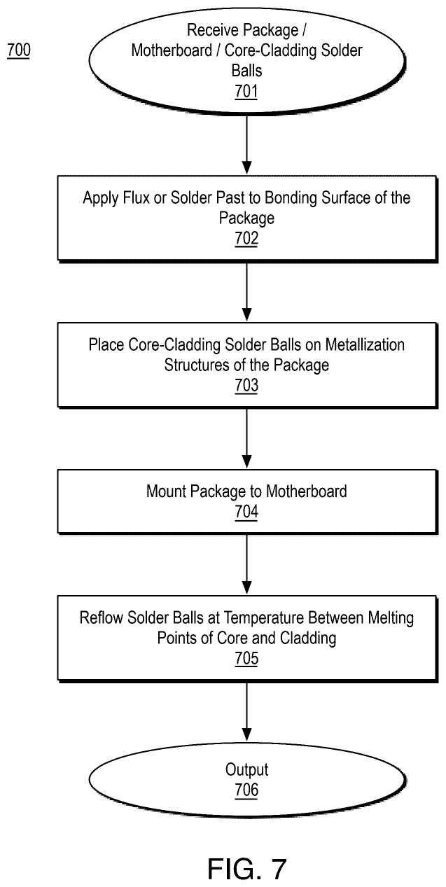

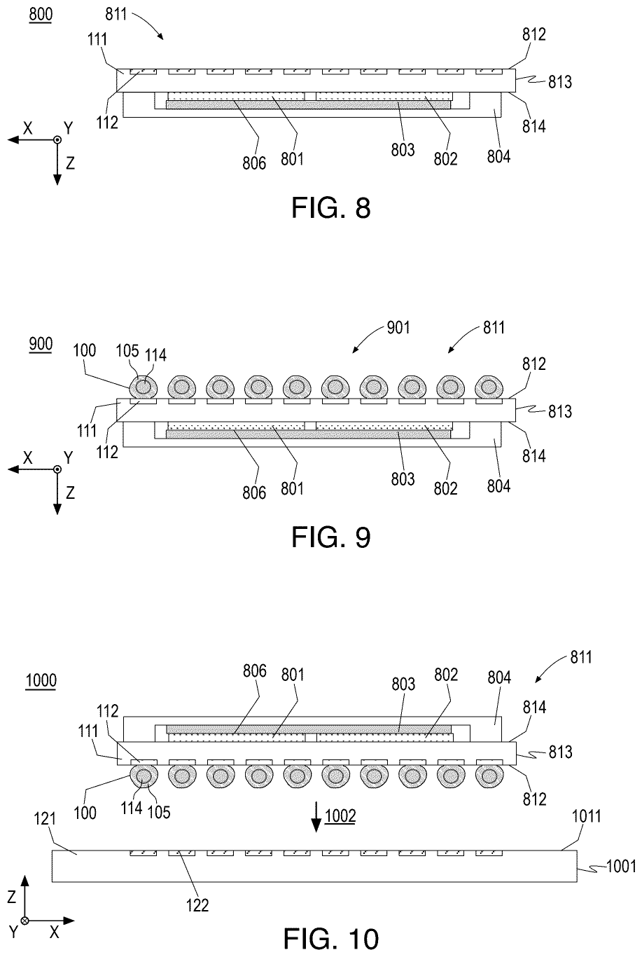

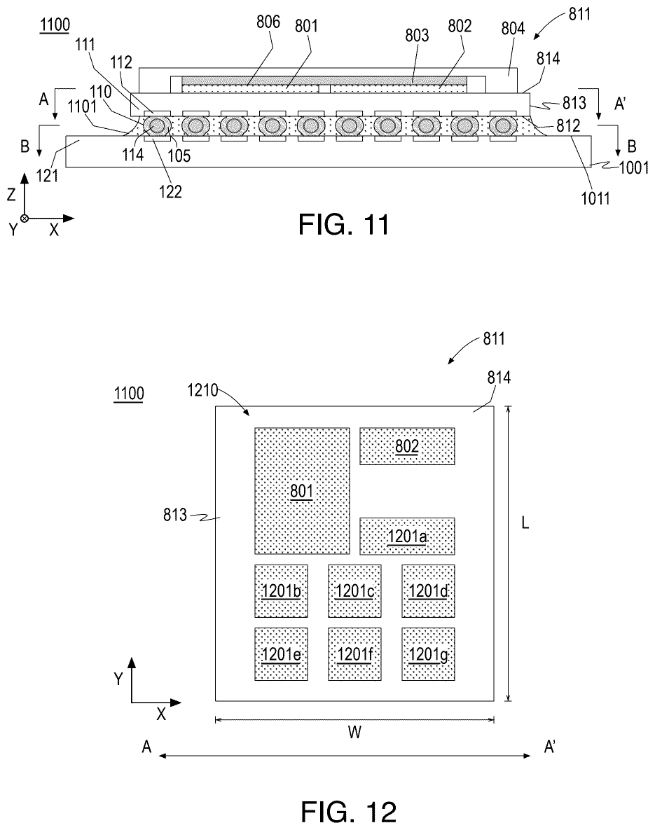

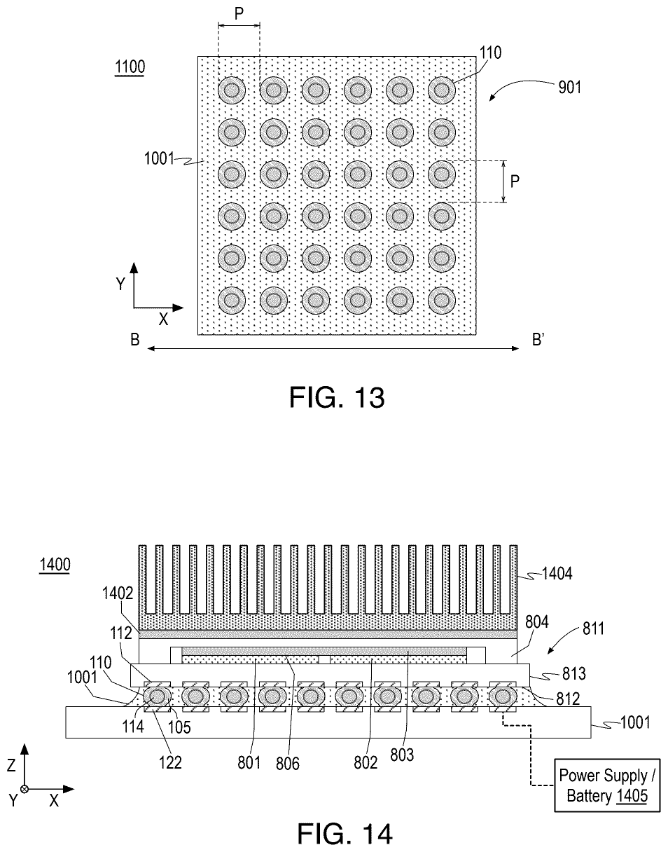

FIG. 7 is a flow diagram illustrating an example process 700 for assembling a device or system including a solder ball interconnect structure having an inner core and a shell of different metal alloys, arranged in accordance with some embodiments. FIGS. 8, 9, 10, and 11 cross-sectional side views of integrated circuit device structures as the operations of process 700 are performed to assemble a device or system including a solder ball interconnect structure having an inner core and a shell of different metal alloys, arranged in accordance with some embodiments. FIG. 12 is a cross-sectional top-down view of the integrated circuit device structure of FIG. 11 showing an exemplary integrated circuit die layout, arranged in accordance with some embodiments. FIG. 13 is a cross-sectional top-down view of the integrated circuit device structure of FIG. 11 showing an exemplary solder interconnect layout, arranged in accordance with some embodiments. FIG. 14 is a cross-sectional side view of the integrated circuit device structure of FIG. 11 after incorporation into a system, arranged in accordance with some embodiments.

As shown, process 700 begins at operation 701, where workpieces, such as an IC package, a motherboard, and solder balls having a SAC inner core and a tin-bismuth shell or cladding are received for processing. The solder balls may optionally have a nickel coating on the SAC inner core and between the SAC inner core and the tin-bismuth shell. Although discussed with respect to solder balls having a SAC inner core, a tin-bismuth shell or cladding, and an optional nickel coating on the SAC inner core, any solder balls discussed herein may be deployed in process 700. The microelectronics board, although illustrated with respect to a motherboard, may be any suitable microelectronics board, substrate, or the like. The microelectronics board may be preprocessed to form exposed metallization structures (e.g., metal bond pads) embedded in a dielectric layer for subsequent bonding. Furthermore, the IC package may be any suitable form factor and the IC package may also be preprocessed to form exposed metallization structures (e.g., metal bond pads) embedded in a dielectric layer for subsequent bonding. The solder balls may be any suitable solder balls having an inner core and a shell of different metal alloys, such as solder balls 100, 200.

FIG. 8 illustrates an example integrated circuit device structure 800 including an IC package 811 to be bonded to a microelectronics substrate. IC package 811 may be characterized as an IC device, an IC system, a surface mountable device or system, or the like. For example, IC package 811 and IC device 113 may share any characteristics. As shown, IC package 811 includes any number IC dies 801, 802 mounted to and electrically coupled to a substrate 813. Substrate 813 may be any suitable substrate such as an interposer, a printed circuit board, or the like. As shown, substrate 813 includes metallization structures 112 embedded in dielectric material 11. One or more IC dies 801, 802 are attached to a first surface 814 of substrate 813 by a number of interconnects (not shown) therebetween, which may be characterized as IC die level interconnects. Additional metal routing may extend through substrate 813 to connect the IC die level interconnects to metallization structures 112, which may be characterized as package level interconnects. For example, metallization structures 112 may be copper bond pads. Substrate 813 also includes a second surface 812 to be bonded to a microelectronics board. IC dies 801, 802 may be any appropriate devices, including, but not limited to, a microprocessor, a die complex, a multichip complex, a chipset, a graphics device, a wireless device, a memory device, an application specific integrated circuit device, artificial intelligence compute devices, cloud computing devices, telecommunication devices, combinations thereof, stacks thereof, or the like.

Integrated circuit device structure 800 further includes a thermal interface material (TIM) 803 disposed on a surface 806 of IC dies 801, 802. TIM 803 may include any suitable thermal interface material and may be characterized as TIM 1. An integrated heat spreader 804, having a surface on TIM 803 extends over IC dies 801, 802, and is mounted to substrate 813. Integrated heat spreader 804 may include a planar structure (e.g., in the x-y plane) having a surface on TIM 803 and extensions projecting from the surface of the planar structure into contact with substrate 813. Integrated heat spreader 804 may be any appropriate thermally conductive material, including, but not limited to copper, aluminum, nickel, alloys thereof, and the like. Although illustrated with respect to integrated circuit device structure 800 having TIM 803 and integrated heat spreader 804 during bonding, such materials and structures may be formed and attached after surface mount of IC package 811 to a microelectronics board.

Returning to FIG. 7, processing continues at operation 702, where flux or solder paste is optionally applied to the bonding surface of the package, and at operation 703, where the solder balls having a SAC inner core, a tin-bismuth shell or cladding, and an optional nickel coating on the SAC inner core, such as solder balls 100, 200, are placed on the bonding surface of the package. The flux or solder paste may be applied using any suitable technique or techniques and may clean the surface of the package substrate and promote adhesion. The solder balls having a SAC inner core, a tin-bismuth shell or cladding, and an optional nickel coating on the SAC inner core may be placed on the package substrate using any suitable technique or techniques such as automated placement techniques. In some embodiments, the flux holds the solder balls in place for continued processing. In some embodiments, the solder balls may be heat treated or reflowed to bond to the underlying metallization structures.

FIG. 9 illustrates an example integrated circuit device structure 900 similar to integrated circuit device structure 800 after placement of solder balls 100 on metallization structures 112. As discussed, solder balls 100 may be placed on metallization structures 112 using any suitable technique or techniques. In some embodiments, solder balls 100 are placed after application of a flux material (not shown). Each of solder balls 100 includes inner core 114 surrounded by shell 105. Although illustrated with respect to solder balls 100, any solder balls discussed herein such as solder balls 200 may be deployed. In some embodiments, solder balls 100 are in a grid pattern 901 (e.g., a ball grid array), as illustrated herein below with respect to FIG. 13. As shown in FIG. 9, solder balls 100 are attached to second surface 812 (e.g., a land side) of IC package 811 using any suitable solder ball attach process. Notably, the overall ball attach performance of solder balls 100 (e.g., solder balls having a SAC inner core, a tin-bismuth shell or cladding, and an optional nickel coating on the SAC inner core) allows for lower temperature reflow operations (e.g., less than or equal to 190° C.).

Returning to FIG. 7, processing continues at operation 704, where the IC package is mounted to a microelectronics board such as a motherboard, and at operation 705 where the solder balls having a SAC inner core, a tin-bismuth shell or cladding, and an optional nickel coating on the SAC inner core are reflowed to form solder ball interconnect structure 110 having a SAC inner core, a tin-bismuth shell or cladding, and an optional nickel coating on the SAC inner core, as discussed herein.

The IC package may be mounted to the microelectronics board using any suitable technique or techniques such as pick and place techniques. The solder balls may be reflowed at any suitable temperature such as a temperature of not more than 190° C. As discussed, such low temperature solder reflow temperatures advantageously do not warp the IC package and/or microelectronics board to the extent that a reliable solder bond cannot be formed therebetween. Processing continues at operation 706, where the surface mounted IC package and microelectronics board are output for continued processing such as inclusion in a high-performance computing product.

FIG. 10 illustrates an example integrated circuit device structure 1000 similar to integrated circuit device structure 900 as IC package 811 is being mounted to a microelectronics board 1001. For example, microelectronics board 1001 and host component 123 may share any characteristics. Microelectronics board 1001 may include any number of components (not shown) attached to a first surface 1011 thereof and/or embedded within microelectronics board 1001. Microelectronics board 1001 and substrate 813 may include a number of dielectric material layers that may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra-low-k dielectrics (dielectric constants less than about 3.6), including, but not limited to, carbon doped dielectrics, fluorine doped dielectrics, porous dielectrics, organic polymeric dielectrics, and the like. Conductive routes within microelectronics board 1001 and substrate 813 may be a combination of conductive traces and conductive vias extending through the plurality of dielectric material layers. The conductive traces and the conductive vias may be made of any appropriate conductive material, including but not limited to, metals, such as copper, silver, nickel, gold, and aluminum, alloys thereof, and the like. Microelectronics board 1001 may be a cored substrate or a coreless substrate. Microelectronics board 1001 may be characterized as an electronics substrate.

Placement operation 1002 aligns IC package 811 over microelectronics board 1001 and places IC package 811 onto microelectronics board 1001 such that solder balls 100 come into contact with corresponding ones of metallization structures 122. For example, metallization structures 122 may be BGA bond pads contacted by solder balls 100, 200 which solder balls having a SAC inner core, a tin-bismuth shell or cladding, and an optional nickel coating on the SAC inner core.

FIG. 11 illustrates an example integrated circuit device structure 1100 similar to integrated circuit device structure 1000 after reflow of solder balls 100 to form solder ball interconnect structure 110 and after application of underfill material 1101. Solder balls 100 may be reflowed to form solder ball interconnect structures 110 using any suitable technique or techniques. For example, the reflow may be a low temperature solder reflow not exceeding a temperature of 190° C. During reflow, shells 105 of solder balls 100 are heated to a molten state (but inner cores 114 are not heated to a molten state) to from an electrical bond to each of metallization structure 112 and metallization structure 122. As shown, after reflow, solder ball interconnect structures 110 are in contact with and electrically couple metallization structures 112 and metallization structures 122. Solder ball interconnect structures 110 include SAC inner core, a tin-bismuth shell or cladding, and an optional nickel coating on the SAC inner core, as well as any other features or characteristics discussed herein.

An underfill material 1101, such as an epoxy material, may be disposed between second surface 812 of substrate 813 and first surface 1011 of microelectronics board 1001, and surrounding solder interconnect structures 110. Underfill material 1101 may be dispensed between first surface 1011 of microelectronics board 1001 and second surface 812 of substrate 813 as a viscous liquid and then hardened with a curing process. Underfill material 1101 may also be a molded underfill material. Underfill material 1101 may provide structural integrity and may prevent contamination, for example.

FIG. 12 is a cross-sectional top-down view of integrated circuit device structure 1100 taken at plane A-A′. As shown in FIG. 12, IC dies 801, 802 may be a part of an IC die complex 1210 coupled to first surface 814 of substrate 813. As shown, IC die complex 1210 may include any number of IC dies 801, 802, 1201a-g, which may be laterally arrayed on first surface 814 of substrate 813 and/or stacked over first surface 814 of substrate 813. IC dies 801, 802, 1201a-g include any appropriate devices, including, but not limited to, microprocessors, chipsets, graphics devices, wireless device, memory devices, application specific integrated circuit devices, artificial intelligence compute devices, cloud computing devices, telecommunication devices, combinations thereof, stacks thereof, or the like.

Notably, the SAC/LTS core/shell solder material structures and techniques discussed herein provide for attachment of large area (e.g., large form factor) IC packages 811 at low temperature such that difficulties associated with warpage, which occurs at higher reflow temperatures, are avoided. For example, the discussed solder materials and techniques enable substrate 813 to have larger length L and width W dimensions such that the area L×W of substrate 813 is in the range of 4,800-6,400 mm² or more.

FIG. 13 is a cross-sectional top-down view of integrated circuit device structure 1100 taken at plane B-B′. As shown in FIG. 13, solder ball interconnect structures 110 may be arrayed in grid pattern 901 having a uniform x- and y-dimension pitch P. As used herein, the term pitch indicates a dimension taken between like features. Pitch P may be any suitable value such as 900 to 1,200 microns. In some embodiments, pitch P is about 1 mm. For example, solder ball interconnect structures 110 may provide a ball grid array (BGA) coupling between metallization structures 112 of IC package 811 and metallization structures 122 of microelectronics board 1001.

FIG. 14 is a cross-sectional side view of the integrated circuit device structure 1100 after incorporation into a system such as a microelectronic device assembly 1400. As shown, microelectronic device assembly 1400 includes metallization structures 122 of microelectronics board 1001 (or host component 123, refer to FIG. 1A), metallization structures 112 of IC package 811 (or IC device 113, refer to FIG. 1), and solder ball interconnect structures 110 coupling metallization structures 122 and metallization structures 112. As discussed, solder ball interconnect structures 110 each includes inner core 114 that includes tin, silver, and copper (e.g., SAC) and shell 105 that includes tin and bismuth (e.g., Sn—Bi).

As shown, FIG. 14 is an illustration of microelectronic device assembly 1400 assembly and deployment of heat removal solutions to integrated circuit device structure 1100. Microelectronic device assembly 1400 may deploy solder ball interconnect structures discussed herein having a SAC inner core, a tin-bismuth shell or cladding, and an optional nickel coating on the SAC inner core. Microelectronic device assembly 1400 includes a power supply 1405 coupled to one or both of microelectronics board 1001 and IC package 811. Power supply 1405 may include a battery, voltage converter, power supply circuitry, or the like. Microelectronic device assembly 1400 further includes a TIM 1402 disposed on a top surface of integrated heat spreader 804. TIM 1402 may include any suitable thermal interface material and may be characterized as TIM 2, while TIM 803 is characterized as TIM 1. TIM 1402 and TIM 803 may be the same materials, or they may be different. A heat sink 1404 (e.g., an exemplary heat dissipation device or thermal solution) is on TIM 1402 and dissipates heat. Microelectronic device assembly 1400 may be used in desktop and server form factors. In other contexts, a heat solution such as a heat pipe or heat spreader may be mounted directly on TIM 1402. Such assemblies may be used in smaller form factor devices. Other heat dissipation devices may be used.

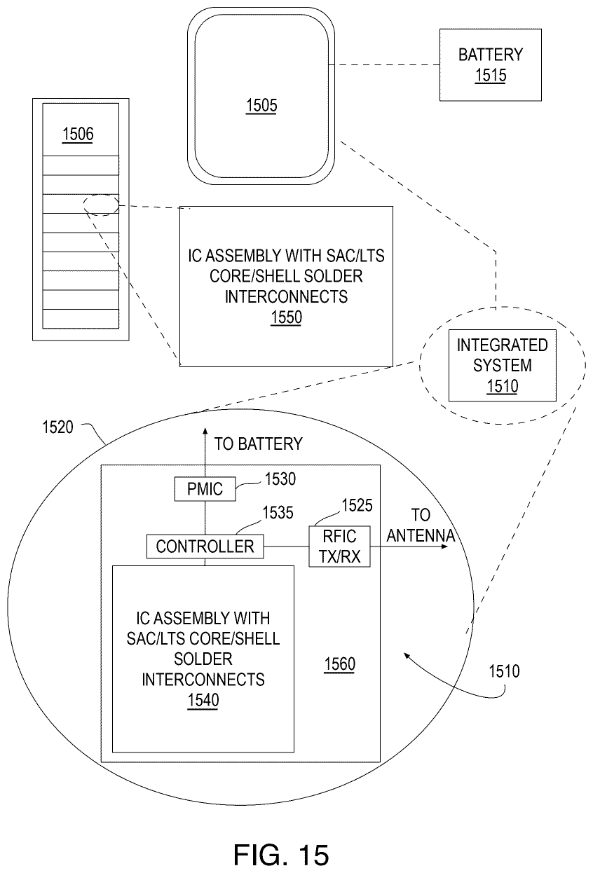

FIG. 15 illustrates exemplary systems employing an assembly including a solder ball interconnect structure having an inner core and a shell of different metal alloys, in accordance with some embodiments. The system may be a mobile computing platform 1505 and/or a data server machine 1506, for example. Either may employ an assembly including a solder ball interconnect structure having an inner core and a shell of different metal alloys as described elsewhere herein. Data server machine 1506 may be any commercial server, for example including any number of high-performance computing platforms disposed within a rack and networked together for electronic data processing, which in the exemplary embodiment includes an IC die assembly 1550 with an assembly including a solder ball interconnect structure having an inner core and a shell of different metal alloys as described elsewhere herein. Mobile computing platform 1505 may be any portable device configured for each of electronic data display, electronic data processing, wireless electronic data transmission, or the like. For example, mobile computing platform 1505 may be any of a tablet, a laptop computer, etc., and may include a display screen (e.g., a capacitive, inductive, resistive, or optical touchscreen), a chip-level or package-level integrated system 1510, and a battery 1515. Although illustrated with respect to mobile computing platform 1505, in other examples, chip-level or package-level integrated system 1510 and a battery 1515 may be implemented in a desktop computing platform, an automotive computing platform, an internet of things platform, or the like. As discussed below, in some examples, the disclosed systems may include a sub-system 1560 such as a system on a chip (SOC) or an integrated system of multiple ICs, which is illustrated with respect to mobile computing platform 1505.

Whether disposed within integrated system 1510 illustrated in expanded view 1520 or as a stand-alone packaged device within data server machine 1506, sub-system 1560 may include memory circuitry and/or processor circuitry 1540 (e.g., RAM, a microprocessor, a multi-core microprocessor, graphics processor, etc.), a power management integrated circuit (PMIC) 1530, a controller 1535, and a radio frequency integrated circuit (RFIC) 1525 (e.g., including a wideband RF transmitter and/or receiver (TX/RX)). As shown, one or more IC dice, such as memory circuitry and/or processor circuitry 1540 may be assembled and implemented such that one or more are incorporated in a system having an assembly including a solder ball interconnect structure having an inner core and a shell of different metal alloys as described herein. In some embodiments, RFIC 1525 includes a digital baseband and an analog front end module further comprising a power amplifier on a transmit path and a low noise amplifier on a receive path). Functionally, PMIC 1530 may perform battery power regulation, DC-to-DC conversion, etc., and so has an input coupled to battery 1515, and an output providing a current supply to other functional modules. As further illustrated in FIG. 15, in the exemplary embodiment, RFIC 1525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1540 may provide memory functionality for sub-system 1560, high level control, data processing and the like for sub-system 1560. In alternative implementations, each of the SOC modules may be integrated onto separate ICs coupled to a package substrate, interposer, or board.

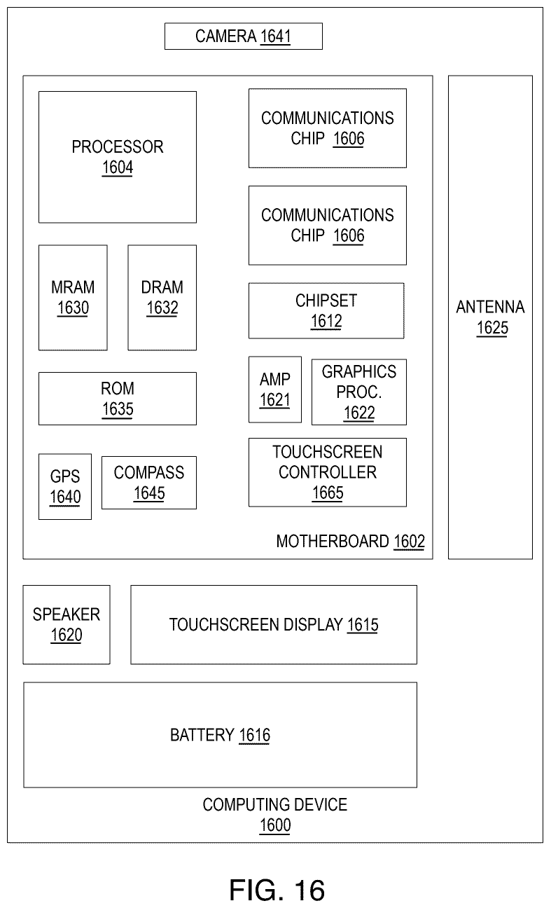

FIG. 16 is a functional block diagram of an electronic computing device 1600, in accordance with some embodiments. For example, device 1600 may, via any suitable component therein, employ an assembly including a solder ball interconnect structure having an inner core and a shell of different metal alloys in accordance with any embodiments described elsewhere herein. For example, any component may be electrically coupled to a motherboard or package substrate 1602 via a solder ball interconnect structure having an inner core and a shell of different metal alloys. Device 1600 further includes motherboard or package substrate 1602 hosting a number of components, such as, but not limited to, a processor 1604 (e.g., an applications processor). Processor 1604 may be physically and/or electrically coupled to motherboard or package substrate 1602. In general, the term “processor” or “microprocessor” may refer to any device or portion of a device that processes electronic data from registers and/or memory to transform that electronic data into other electronic data that may be further stored in registers and/or memory.

In various examples, one or more communication chips 1606 may also be physically and/or electrically coupled to motherboard or package substrate 1602. In further implementations, communication chips 1606 may be part of processor 1604. Depending on its applications, computing device 1600 may include other components that may or may not be physically and electrically coupled to motherboard or package substrate 1602. These other components include, but are not limited to, volatile memory (e.g., DRAM 1632), non-volatile memory (e.g., ROM 1635), flash memory (e.g., NAND or NOR), magnetic memory (MRAM 1630), a graphics processor 1622, a digital signal processor, a crypto processor, a chipset 1612, an antenna 1625, touchscreen display 1615, touchscreen controller 1665, battery 1616, audio codec, video codec, power amplifier 1621, global positioning system (GPS) device 1640, compass 1645, accelerometer, gyroscope, speaker 1620, camera 1641, and mass storage device (such as hard disk drive, solid-state drive (SSD), compact disk (CD), digital versatile disk (DVD), and so forth, or the like.

Communication chips 1606 may enable wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1606 may implement any of a number of wireless standards or protocols, including, but not limited to, those described elsewhere herein. As discussed, computing device 1600 may include a plurality of communication chips 1606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, a solder ball comprises an inner core comprising an alloy of tin, silver, and copper, and a shell surrounding the inner core, the shell comprising an alloy of tin and bismuth.

In one or more second embodiments, further to the first embodiments, at least a portion of the shell comprises substantially pure tin-bismuth with not less than 30 wt. % and not more than 57% wt. % bismuth, and a balance of tin.

In one or more third embodiments, further to the first or second embodiments, the portion of the shell comprises not more than 1 wt. % silver or antimony.

In one or more fourth embodiments, further to the first through third embodiments, the portion of the shell comprises pure tin-bismuth.

In one or more fifth embodiments, further to the first through fourth embodiments, the shell is directly on the inner core, the inner core comprising bismuth.

In one or more sixth embodiments, further to the first through fifth embodiments, the solder ball further comprises a coating on the inner core and between the inner core and the shell, the coating comprising nickel.

In one or more seventh embodiments, further to the first through sixth embodiments, the coating has a thickness of not less than 1 micron and not more than 5 microns.

In one or more eighth embodiments, further to the first through seventh embodiments, the inner core is absent bismuth.

In one or more ninth embodiments, further to the first through eighth embodiments, the shell has a thickness of not less 0.8 microns and not more than 150 microns.

In one or more tenth embodiments, further to the first through ninth embodiments, an apparatus or a system comprises a first metallization structure of a host component and a second metallization structure of an integrated circuit (IC) device coupled by an interconnect structure comprising the solder material of any of the first through tenth embodiments.

In one or more eleventh embodiments, an apparatus comprises a first metallization structure of a host component, a second metallization structure of an integrated circuit (IC) device, and an interconnect structure coupling the first metallization structure and the second metallization structure, the interconnect structure comprising an inner metal core comprising tin, silver, and copper, and a metal cladding surrounding the inner metal core, the metal cladding comprising tin and bismuth.

In one or more twelfth embodiments, further to the eleventh embodiments, the metal cladding comprises substantially pure tin-bismuth.

In one or more thirteenth embodiments, further to the eleventh or twelfth embodiments, the metal cladding comprises not less than 30 wt. % and not more than 57% wt. % bismuth.

In one or more fourteenth embodiments, further to the eleventh through thirteenth embodiments, the metal cladding further comprises silver or antimony.

In one or more fifteenth embodiments, further to the eleventh through fourteenth embodiments, the apparatus further comprises a coating having a thickness of not less than 1 micron and not more than 5 microns on the inner metal core and between the inner metal core and the metal cladding, the coating comprising nickel.

In one or more sixteenth embodiments, further to the eleventh through fifteenth embodiments, the inner metal core has a cross-sectional dimension of not less than 200 microns and not more than 700 microns and the metal cladding has a thickness of not less than 0.8 microns and not more than 150 microns.

In one or more seventeenth embodiments, further to the eleventh through sixteenth embodiments, the apparatus further comprises a power supply coupled to one of the host component or the IC device.

In one or more eighteenth embodiments, an apparatus comprises a microelectronics board, an integrated circuit (IC) package comprising one or more IC devices, and an interconnect structure electrically coupling the microelectronics board to the IC package, the interconnect structure comprising an inner core having a first melting point, and a cladding surrounding the inner core, the cladding having a second melting point, wherein the first melting point is not less than 40° C. greater than the second melting point.

In one or more nineteenth embodiments, further to the eighteenth embodiments, the inner core comprises an alloy of tin, silver, and copper, and the cladding comprises an alloy of tin and bismuth.

In one or more twentieth embodiments, further to the eighteenth or nineteenth embodiments, at least a portion of the inner core comprises about 96.5 wt. % tin, about 3 wt. % silver, and about 0.5 wt. % copper, and at least a portion of the cladding comprises substantially pure tin-bismuth with not less than 30 wt. % and not more than 57% wt. % bismuth, and a balance of tin.

In one or more twenty-first embodiments, further to the eighteenth through twentieth embodiments, the portion of the cladding comprises not more than 1 wt. % silver or antimony.

In one or more twenty-second embodiments, further to the eighteenth through twenty-first embodiments, the apparatus further comprises a coating on the inner core and between the inner core and the cladding, the coating comprising substantially pure nickel and having a thickness of not more than 5 microns.

In one or more twenty-third embodiments, further to the eighteenth through twenty-second embodiments, the apparatus further comprises a power supply coupled to one of the host component or the IC device.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A solder ball, comprising:
an inner core comprising an alloy of tin, silver, and copper; and
a shell surrounding the inner core, the shell comprising an alloy of tin and bismuth.

2. The solder ball of claim 1, wherein at least a portion of the shell comprises substantially pure tin-bismuth with not less than 30 wt. % and not more than 57% wt. % bismuth, and a balance of tin.

3. The solder ball of claim 2, wherein the portion of the shell comprises not more than 1 wt. % silver or antimony.

4. The solder ball of claim 2, wherein the portion of the shell comprises pure tin-bismuth.

5. The solder ball of claim 1, wherein the shell is directly on the inner core, the inner core comprising bismuth.

6. The solder ball of claim 1, further comprising a coating on the inner core and between the inner core and the shell, the coating comprising nickel.

7. The solder ball of claim 6, wherein the coating has a thickness of not less than 1 micron and not more than 5 microns.

8. The solder ball of claim 6, wherein the inner core is absent bismuth.

9. The solder ball of claim 1, wherein the shell has a thickness of not less 0.8 microns and not more than 150 microns.

10. An apparatus, comprising:
a first metallization structure of a host component;
a second metallization structure of an integrated circuit (IC) device; and
an interconnect structure coupling the first metallization structure and the second metallization structure, the interconnect structure comprising:
an inner metal core comprising tin, silver, and copper; and
a metal cladding surrounding the inner metal core, the metal cladding comprising tin and bismuth.

11. The apparatus of claim 10, wherein the metal cladding comprises substantially pure tin-bismuth.

12. The apparatus of claim 11, wherein the metal cladding comprises not less than 30 wt. % and not more than 57% wt. % bismuth.

13. The apparatus of claim 10, wherein the metal cladding further comprises silver or antimony.

14. The apparatus of claim 10, further comprising a coating having a thickness of not less than 1 micron and not more than 5 microns on the inner metal core and between the inner metal core and the metal cladding, the coating comprising nickel.

15. The apparatus of claim 10, wherein the inner metal core has a cross-sectional dimension of not less than 200 microns and not more than 700 microns and the metal cladding has a thickness of not less than 0.8 microns and not more than 150 microns.

16. An apparatus, comprising:
a microelectronics board;
an integrated circuit (IC) package comprising one or more IC devices; and
an interconnect structure electrically coupling the microelectronics board to the IC package, the interconnect structure comprising:
an inner core having a first melting point; and
a cladding surrounding the inner core, the cladding having a second melting point, wherein the first melting point is not less than 40° C. greater than the second melting point.

17. The apparatus of claim 16, wherein the inner core comprises an alloy of tin, silver, and copper, and the cladding comprises an alloy of tin and bismuth.

18. The apparatus of claim 17, wherein at least a portion of the inner core comprises about 96.5 wt. % tin, about 3 wt. % silver, and about 0.5 wt. % copper, and at least a portion of the cladding comprises substantially pure tin-bismuth with not less than 30 wt. % and not more than 57% wt. % bismuth, and a balance of tin.

19. The apparatus of claim 18, wherein the portion of the cladding comprises not more than 1 wt. % silver or antimony.

20. The apparatus of claim 16, further comprising a coating on the inner core and between the inner core and the cladding, the coating comprising substantially pure nickel and having a thickness of not more than 5 microns.
